(19) United States
(12) Patent Application Publication
(10) Pub. No.: US 2026/0223646 A1
(43) Pub. Date: Jul. 30, 2026

(54) METHOD FOR MANUFACTURING A WAFER COMPRISING TWO ZONES HAVING A WETTABILITY CONTRAST GREATER THAN 90° AND WAFER THUS MANUFACTURED

(71) Applicant: COMMISSARIAT A L'ENERGIE ATOMIQUE ET AUX ENERGIES ALTERNATIVES, Paris (FR)

(72) Inventors: Carine LADNER, Grenoble cedex 09 (FR); Emilie BOURJOT, Grenoble cedex 09 (FR); Alice BOND, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 19/140,149

(22) PCT Filed: Dec. 18, 2023
(86) PCT No.: PCT/EP2023/086346

§ 371 Date: Jun. 17, 2025

(30) Foreign Application Priority Data
Dec. 21, 2022 (FR) FR2214148

(51) Int. Cl. H10P 90/00; H10W 70/05; H10W 80/00; H10W 90/10

(52) U.S. Cl. CPC H10P 90/1904; H10W 70/093; H10W 80/314; H10W 80/327; H10W 90/10

(57) ABSTRACT

A method for manufacturing a wafer comprising two zones having a wettability contrast greater than 90° and a wafer thus manufactured. The method relates to the field of 3D interconnection technologies for microelectronics but relates to any application requiring a high wettability contrast on the micrometric scale. The method makes it possible to manufacture a wafer comprising a main surface having a solid zone and a micro- or nano-structured zone having, between them, a wettability contrast greater than 90°, each structured zone extending around a solid zone, the wafer comprising a substrate which comprises a first level with the basis of a semiconductor material and a second level with the basis of a dielectric material, the solid zone and each structured zone being formed in the second level of the substrate and each structured zone having a plurality of terminals with the basis of said dielectric material, the wafer being such that the terminals have faceted ends.

### TECHNICAL FIELD OF THE INVENTION

The present invention mainly relates to the field of 3D interconnection technologies for microelectronics but can relates to any type of applications requiring having a high wettability contrast on the micrometric scale.

The present invention relates more specifically to the die-to-wafer (DTW) hybrid bonding die self-assembly technique.

The present invention particularly advantageously applies to the self-assembly of microelectronic components for their 3D integration. In the case of self-assembly, the invention can relate to the self-assembly of types of dies, other than microelectronic dies, and in particular, the self-assembly of microsystems, of biological dies, of fluid devices, of optical devices, etc.

### PRIOR ART

3D interconnection technologies have been developed to increase the number of functionalities per surface unit. Die-to-wafer (DTW)-type transfer techniques are particularly interesting for heterogenic 3D integration, which offers the advantage of assembling different technologies on one same receiving circuit, or equivalently, on one same functionalised receiving wafer.

Current DTW methods are divided into two categories:
a. Pick-and-place transfer methods: the dies are taken by a robot and aligned one by one on a receiving wafer (below, also called “target wafer”). However, in these methods, the alignment accuracy is inversely proportional to the transfer rate; and
b. Self-assembly transfer methods: the dies are transferred and roughly pre-aligned by pick-and-place equipment to the receiving wafer. The final alignment is performed by the capillarity forces of a liquid at the interface between the die and a transfer zone of the die onto the receiving wafer.

More specifically, the self-assembly consists of depositing a waterdrop on a transfer zone of a die which is hydrophilic and to then approach the die, so as to obtain its self-alignment thanks to the capillarity forces between the two surfaces in the presence of either side of the drop. This technique can make it possible to increase both alignment accuracy and transfer rate. The transfer of dies can further be performed individually or collectively.

The self-assembly therefore requires adaptations of usual die-to-wafer (DTW) bonding integration, with, in particular, the definition of hydrophilic and hydrophobic zones on the target wafer, preferably with a high surface energy contrast between both.

In this case, it is noted that the hydrophilic, hydrophobic and super-hydrophobic characters of the surfaces are characterised by their drop angle value, which are respectively less than 90°, between 90 and 120°, and greater than 120°.

In reference to FIG. 1, one of the ways to create wettability contrast (difference between the drop angle a of the transfer zone 101 of a die and the drop angle β of the zone 102 surrounding the transfer zone 101) is to generate:
a. a mesa 15, of several micrometres thick, in general, on the surface 10 of the receiving wafer 1, such that the upper surface of the mesa 15 constitutes a receiving zone 101 of a die, and/or
b. a mesa, of several micrometres thick, in general, on the surface of each die to be transferred, and/or
c. a chemical contrast, between each receiving zone 101 on the surface of the receiving wafer 1 and the inter-die zone 102 which surrounds each receiving zone 101, even between the receiving zone 101 on the surface of the receiving wafer 1 and the rest of the surface of the receiving wafer 1, by means of a hydrophilic layer 1000 on the upper surface of each mesa, and/or
d. a chemical contrast, between the receiving zones 101 on the surface of the receiving wafer 1 and the inter-die zones 102, by means of a hydrophobic layer 1001 which covers at least the inter-die zones 102, and if necessary, the perimeter of each mesa 15.

Wettability contrasts of around 90° can thus be obtained.

To generate, on the surface of the receiving wafer, a wettability contrast between the receiving zones of the dies to be transferred and the zones which surround these receiving zones, it is also possible to generate, at least at the zones which surround the receiving zones, a micro- or nano-structured surface, i.e. a surface having a micro- or nano-roughness, in particular creating the conditions for observing a lotus effect. In particular, when such a surface structuration is further associated with the presence of a chemically hydrophobic coating, it is possible to reach wettability contrasts greater than 120°. A super-hydrophobia is thus achieved, which makes it possible to have a better alignment accuracy.

A method for manufacturing hydrophilic receiving sites surrounded by their super-hydrophobic surface by means of a dry etching of Si obtained by deep reactive ion etching, which makes it possible to obtain black silicon, i.e. a very rough silicon surface made of small needles is thus known from the articles entitled, “Surface-Tension-Driven Self-Alignment of Microchips on Black-Silicon-Based Hybrid Template in Ambient Air” by Ali Shah et al. and appeared in JOURNAL OF MICROELECTROMECHANICAL SYSTEMS, VOL. 22, NO. 3, JUNE 2013, 739.

However, obtaining, by deep reactive ion etching, such a super-hydrophobic surface, reproductively, is not easy. In addition, black silicon can generate a significant quantity of silicon debris which breaks off, in the form of particles, from the surface, because the microneedles generated are very irregular and in fragile locations. This is therefore a notable disadvantage for the hybrid bonding technique, which requires a surface which is as clean as possible and has no particles.

In addition, the method described in the abovementioned article requires to have access to the silicon of the substrate in the inter-die zones, which can involve having to remove all the materials deposited on the target wafer during the manufacture of the circuits. This can prove to be difficult and expensive according to the complexity of the stacks of materials, in particular, in the upper levels of the receiving wafer which are usually functionalised to be used as interconnection levels between the target wafer and the dies.

An aim of the present invention is therefore to propose a method for manufacturing a wafer, comprising a main surface having at least one solid zone and one micro- or nano-structured zone having, between them, a wettability contrast greater than 90°, and preferably greater than 120°, each micro- or nano-structured zone extending around a solid zone, which makes it possible to overcome at least one of the disadvantages of the prior art.

An aim of the present invention is more specifically to propose such a method resulting in the manufacture of a wafer suitable for the self-assembly of dies by die-to-wafer-type hybrid bonding.

Other aims, features and advantages of the present invention will appear upon examining the description below and the accompanying drawings. It is understood that other advantages can be incorporated.

### SUMMARY OF THE INVENTION

To achieve this aim, according to an embodiment, a method is provided, for manufacturing a wafer comprising a main surface having at least one solid zone and one micro- or nano-structured zone having, between them, a wettability contrast greater than 90°, and preferably greater than 120°, each micro- or nano-structured zone extending around a solid zone, the method comprising the following steps:
a. Providing a substrate comprising a first level with the basis of a semiconductor material and a second level with the basis of a dielectric material, the second level extending over the first level,
b. Forming, on an exposed surface of the second level of the provided substrate, a layer with the basis of a sacrificial material, such as a resin, having at least one first zone, over which a solid layer with the basis of said sacrificial material extends, and a second zone having a surface, structured by a plurality of micrometric or nanometric terminals with the basis of said sacrificial material, each first zone being surrounded by a second zone and each first zone extending over a surface, of at least one order of magnitude, greater than a micrometric or nanometric surface, over which each terminal with the basis of said sacrificial material extends, then
c. Etching a part of the layer with the basis of said previously formed sacrificial material and a part of the second level of the substrate, so as to form, in the second level of the substrate, said at least one solid zone at each first zone and each micro- or nano-structured zone at each second zone, each micro- or nano-structured zone having a plurality of terminals with the basis of said dielectric material which corresponds to the plurality of terminals with the basis of said sacrificial material.

Among the advantages which result from the manufacturing method such as introduced above, the following are mentioned:
a. The shape, the size and the density of the terminals made of a dielectric material are fully controlled and modulable, since they are determined by the pattern that the layer with the basis of said sacrificial material draws. In the same way, the distance between the solid zone and the micro- or nano-structured zone is also fully controlled and modulable, since it is defined by the pattern that the layer with the basis of said sacrificial material draws; and/or
b. It is thus avoided to generate a solid zone, or mesa, having a very thick thickness on the surface of the wafer, this mesa being obtained, all the same, so as to contribute to reaching a high wettability contrast between the solid zone (or mesa) and the micro- or nano-structured zone.

Optionally, the first aspect of the invention can further have at least any one of the following features, which can be taken separately or in combination:

According to an example, the etching can be followed, by an overetching, until obtaining a lift-off of the terminals with the basis of said sacrificial material. The different in dimension (of an order of magnitude) between each solid layer with the basis of said sacrificial material and each terminal with the basis of said sacrificial material explains that the sacrificial material constituting the terminals with the basis of said sacrificial material is more rapidly consumed by the etching, than the sacrificial material constituting each first zone by a “faceting” phenomenon, which consists of a lateral consumption of the sacrificial material which is added to its consumption from above. Thus, dielectric material-based terminals are thus obtained at the faceted ends, and for example, needle-shaped. Relative to a drop angle obtained with flat terminal heads, this angle being substantially equal to 130°, the faceted head of the terminals obtained following the overetching makes it possible to advantageously achieve a drop angle substantially equal to 160°. A better hydrophobic effect is therefore thus obtained.

According to another example, the formation of the layer with the basis of said sacrificial material can comprise a photolithography step. It thus appears that it is sufficient to apply, on the provided substrate, one single photolithography level to enable the obtaining of a wafer having at least two zones having, between them, a wettability contrast greater than 90°, and preferably greater than 120°. Furthermore, the etching step making it possible to generate the microroughness thus falls under a standard and fully controlled microelectronics technique, which does not generate defects, nor particles. It is very easy to integrate into a method for manufacturing a receiving wafer, intended for the transfer of dies by hybrid bonding of dies, and implements the same types of equipment as the techniques for manufacturing the provided substrate.

According to another example, the etching can be stopped before obtaining a lift-off of the layer with the basis of said sacrificial material to the right of each first zone, the layer with the basis of said sacrificial material remaining to the right of each first zone, preferably having a thickness of between 100 nm and 5 μm. Preferably, the etching comprises an exposure to an etching plasma or to an ion etching.

According to another example, the manufacturing method according to the first aspect of the invention can further comprise, following the etching, the deposition of a layer, preferably conform, with the basis of a hydrophobic material, below called “hydrophobic layer”. For example, the hydrophobic material with the basis of which the hydrophobic layer is constituted, is preferably with the basis of at least one polymer. It comprises, for example, a 0.1% by mass fluorosilane polymer in a hydrofluoroether carrier solvent. For example, the deposition of the hydrophobic layer comprises a spin coating step or a plasma deposition step.

According to another example, the manufacturing method according to the first aspect of the invention can further comprise a step of removing a part of the layer with the basis of said sacrificial material which remains to the right of the first zone after the etching, so as to expose a surface of the second level of the substrate, which is located to the right of each first zone.

According to an example linked to the two preceding examples, the deposition of the hydrophobic layer can be implemented before the lift-off of the part of the layer with the basis of said sacrificial material which remains to the right of the first zone after the etching. Thus, the lift-off of the part of the layer with the basis of said sacrificial material which remains to the right of the first zone results in the removal of the layer with the basis of a hydrophobic material to the right of the solid zone. Subsequently, such that the material with the basis of which is constituted, the second level of the substrate is hydrophilic, the wettability contrast between the solid zone (or mesa) and the micro- or nano-structured zone is advantageously significantly increased.

According to another example, the wafer can constitute a receiving wafer intended for the transfer of microelectronic components, such as microelectronic dies, by hybrid bonding, each solid zone being intended to receive a microelectronic component and each micro- or nano-structured zone being intended to constitute at least one part of a zone between microelectronic components.

According to the preceding example, the second level of the substrate comprising at least one electrical interconnection level extending at least to the right of each solid zone and extending, if necessary, from a solid zone to an adjacent micro- or nano-structured zone, the etching can be stopped before reaching said at least one electrical interconnection level. The method thus makes it possible to preserve the integrity of the insulating and metal materials which can be very numerous in the inter-die zones, and which would be difficult to remove by etching, given their variety.

A second aspect of the invention relates to a wafer comprising a main surface having at least one solid zone and one micro- or nano-structured zone having, between them, a wettability contrast greater than 90°, and preferably greater than 120°, each micro- or nano-structured zone extending around a solid zone, the wafer comprising a substrate which comprises a first level with the basis of a semiconductor material and a second level with the basis of a dielectric material, the second level extending over the first level, said at least one solid zone and each micro- or nano-structured zone being formed in the second level of the substrate and each micro- or nano-structured zone having a plurality of terminals with the basis of said dielectric material, the wafer being mainly such that the terminals with the basis of said dielectric material have faceted ends.

The wafer according to the second aspect of the invention makes it possible to obtain a further increased wettability contrast relative to that, that a wafer supporting terminals offers, each taking the form of a pillar, the cross-section of which remains substantially constant from the base to the vertex.

A third aspect of the invention relates to a method for self-assembling microelectronic components implementing a wafer according to the second aspect of the invention. For example, a plurality of microelectronic components, such as microelectronic dies, are self-assembled on the wafer by die-to-wafer-type hybrid bonding.

A fourth aspect of the invention relates to an assembly comprising a wafer according to the second aspect of the invention and a plurality of microelectronic components, such as microelectronic dies, assembled on the wafer by hybrid bonding.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIG. 1 schematically represents a cross-sectional view of a part of an embodiment of a receiving wafer according to the prior art.

FIG. 2 schematically represents a cross-sectional view of a part of an embodiment of a receiving wafer according to the invention and a microelectronic die located opposite the surface of the receiving wafer, via which the microelectronic die is intended to be assembled by hybrid bonding to the receiving wafer.

FIGS. 3A to 3E schematically illustrate the different steps of an embodiment of the method for manufacturing the receiving wafer illustrated in FIG. 2.

FIG. 4A schematically illustrates a top view of an embodiment of a receiving wafer according to the invention.

FIG. 4B illustrates a magnification over four terminals made of a dielectric material of the embodiment of the receiving wafer according to the invention, which is illustrated in FIG. 4A.

FIGS. 5A and 5B represent photos in the perspective of terminals made of a dielectric material obtained by implementation of an embodiment of the manufacturing method according to the first aspect of the invention, respectively without overetching and with overetching.

FIG. 6A represents a photo in the perspective of a portion of a receiving wafer according to the invention comprising terminals made of a dielectric material and covered with a layer made of a hydrophobic material, which have been obtained by implementation of an embodiment of the manufacturing method according to the first aspect of the invention.

FIG. 6B represents a photo in the perspective of a portion of a receiving wafer according to the invention comprising a receiving mesa obtained by implementation of an embodiment of the manufacturing method according to the first aspect of the invention, the hydrophobic layer covering the flanks of the mesa and the bottom of the main surface of the substrate, but not the upper surface of the mesa.

FIG. 7 schematically represents a cross-sectional view of a part of an embodiment of a receiving wafer according to the invention and a microelectronic die located opposite the surface of the receiving wafer via which the microelectronic die is intended to be assembled by hybrid bonding to the receiving wafer. FIG. 7 corresponds substantially to FIG. 2, except that it further represents the electrical interconnection levels of the receiving wafer and of the microelectronic die.

The drawings are given as examples and are not limiting of the invention. They constitute principle schematic representations intended to facilitate the understanding of the invention and are not necessarily to the scale of practical applications. In particular, the thicknesses of the different layers illustrated in the figures are not representative of reality.

### DETAILED DESCRIPTION OF THE INVENTION

Before starting a detailed review of embodiments of the invention, optional features are stated below, which can optionally be used in association or alternatively:

According to an example, the dielectric material with the basis of which is constituted, the second level of the provided substrate is an oxide of the material with the basis of which is constituted the first level of the substrate.

Alternatively, or complementarily to the preceding example, the material with the basis of which is constituted, the first level of the substrate and/or the second level of the substrate is chosen from among: silicon, germanium, sapphire, etc.

According to an example of the first aspect of the invention, the photolithography step comprises the following substeps:
a. Depositing a layer with the basis of said sacrificial material, for example with the basis of a photosensitive resin, solid on the exposed surface of the second level of the provided substrate,
b. Exposing the layer with the basis of said sacrificial material to a light radiation through a structured photolithography mask, so as to define a negative or a positive of a micro-structuration of said layer with the basis of said sacrificial material, then
c. Chemically etching the layer with the basis of said sacrificial material, so as to obtain the micro-structuration of said layer with the basis of said sacrificial material.

Alternatively to the preceding example, the formation of the layer with the basis of said sacrificial material comprises a screen-printing step or an electron beam photolithography step.

According to another example of the first aspect of the invention, the deposition of the hydrophobic layer can be configured, such that the hydrophobic layer covers each terminal with the basis of said dielectric material and each space between the terminals with the basis of said dielectric material of one same plurality, even if necessary, side edges of each solid zone.

According to another example of the first aspect of the invention, the layer with the basis of said sacrificial material can be formed, so as to have a substantially constant thickness of between 200 nm and 5 μm, preferably between 500 nm and 1.5 μm, and even more preferably, substantially equal to 800 nm.

According to another example of the first aspect of the invention, the layer with the basis of said sacrificial material can be formed, such that each solid zone has at least one transverse dimension of between 100 μm and 20000 μm, preferably between 500 μm and 5000 μm, and even more preferably, substantially equal to 2000 μm.

According to another example of the first aspect of the invention, the layer with the basis of said sacrificial material can be formed, such that two terminals, adjacent to one another, of one same plurality are spaced apart from one another by a distance of between 100 nm and 1 μm, preferably between 200 nm and 800 nm, and even more preferably, substantially equal to 500 nm.

According to another example of the first aspect of the invention, the etching is configured such that each terminal with the basis of said dielectric material has a height of between 100 nm and 5 μm, preferably between 400 nm and 2.5 μm, and even more preferably, substantially equal to 1 μm.

According to an example, the terminals with the basis of said dielectric material of each plurality can be distributed in a matrix manner over the micro- or nano-structured zone in question and/or can have octagonal-shaped cross-sections of characteristic size substantially equal to 500 nm and/or are spaced apart from one another by a minimum distance substantially of between 300 nm and 1 μm.

According to an example of the second aspect of the invention, the wafer can further comprise a hydrophobic layer covering each terminal with the basis of said dielectric material and each space between the terminals with the basis of said dielectric material of one same plurality, even if necessary, side edges of each solid zone, and not covering said at least one solid zone.

According to another example of the second aspect of the invention:
a. each terminal with the basis of said dielectric material can have a height of between 100 nm and 5 μm, preferably between 400 nm and 2.5 μm, and even more preferably, substantially equal to 1 μm, and/or
b. each terminal with the basis of said dielectric material can have at least one transverse dimension of between 100 nm and 2 μm, preferably between 200 nm and 1 μm, and even more preferably, substantially equal to 500 nm, and/or
c. two terminals with the basis of said dielectric material adjacent to one another, of one same plurality, can be spaced apart from one another by a distance of between 100 nm and 1 μm, preferably between 200 nm and 800 nm, and even more preferably, substantially equal to 500 nm.

According to another example of the second aspect of the invention, the wafer can constitute a receiving wafer intended for the transfer of microelectronic components, such as microelectronic dies, by hybrid bonding, each solid zone being intended to receive a microelectronic component and each micro- or nano-structured zone being intended to constitute at least one part of a zone between microelectronic components.

According to another example of the second aspect of the invention, the second level of the substrate can comprise at least one electrical interconnection level extending at least to the right of each solid zone and extending, if necessary, from a solid zone to an adjacent micro- or nano-structured zone, the electrical interconnections flush with the second level of the substrate from an exposed surface of each solid zone and extending from each solid zone at least up to the adjacent micro- or nano-structured zone, and extending more specifically below the plurality of terminals with the basis of said dielectric material of said adjacent micro- or nano-structured zone, by being encapsulated in the dielectric material with the basis of which the second level of the substrate is constituted.

By “hybrid bonding”, this means a bonding obtained between hybrid surfaces, i.e. between surfaces composed of several materials. In the case of 3D interconnections, these materials can be Cu (for the electrical contacts) and SiO₂ (to insulate the contacts from one another). Hybrid bonding can be performed in wafer-to-wafer mode or in die-to-wafer mode.

By “a terminal having a faceted end”, this means a terminal, the cross-section of which develops by decreasing from its base or from a non-zero distance to its base, and up to its end opposite its base. For example, the terminal can have an ogive-shaped or pinhead-shaped end.

By a “micro- or nano-structured zone”, this means a zone having a micro-structuration, i.e. elements which are distinguished by their characteristic micro- or nanometric size. It is mainly a question, in this case, of a zone having a micro- or nano-structured surface.

By a “solid zone”, this means a zone defined opposed to a micro- or nano-structured zone, like a zone having a smooth (or flat) surface in this sense that its roughness is far less, for example, of at least one order of magnitude, than the roughness linked to the micro-structuration of the surface of the micro- or nano-structured zone. For example, the solid zone has a surface roughness less than 0.3 nm.

By a “film with the basis of a material A”, this means a film comprising this material A, and optionally other materials.

By a parameter “substantially equal to/greater than/less than” a given value, this means that this parameter is equal to/greater than/less than the given value, plus or minus 20%, even 10%, of this value. By a parameter “substantially between” two given values, this means that this parameter is, as a minimum, equal to the lowest given value, plus or minus 20%, even 10%, of this value, and as a maximum, equal to the greatest given value, plus or minus 20%, even 10%, of this value.

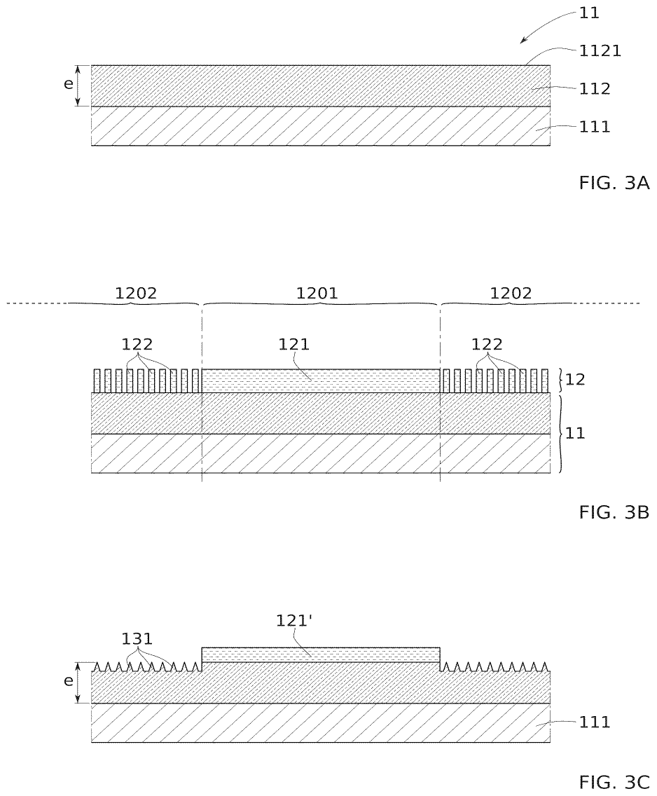

In its broadest acceptance, and in reference to FIG. 2, the first aspect of the invention relates to a method for manufacturing a wafer 1 comprising a main surface 10 having at least one solid zone 101 and one micro- or nano-structured zone 102, below called “structured zone 102”. These zones have, between them, a wettability contrast, which is defined as the difference between the drop angle a associated with the solid zone 101 and the drop angle β associated with the structured zone 102, greater than 90°, and preferably greater than 120°. Moreover, each structured zone 102 extends around a solid zone 101. This acceptance makes it possible to define a wafer and its manufacturing method intended, not only to receive, by transfer, microelectronic components 2, such as microelectronic dies, for their hybrid bonding onto the wafer, but also any other type of applications, and in particular, any type of applications requiring to have a high wettability contrast on the micrometric scale.

This, if thereafter, the invention is described in the scope of its main application, i.e. in the scope of an application for the self-assembly of microelectronic components 2 on the wafer 1 by hybrid bonding of the die-to-wafer type, the invention is not, for all that, limited to this application.

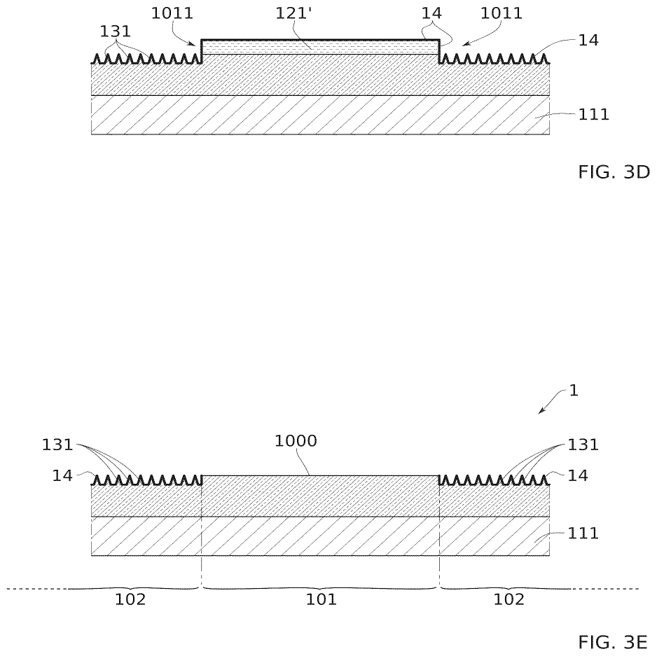

An embodiment of the manufacturing method according to the first aspect of the invention is described below in reference to FIGS. 3A to 3E.

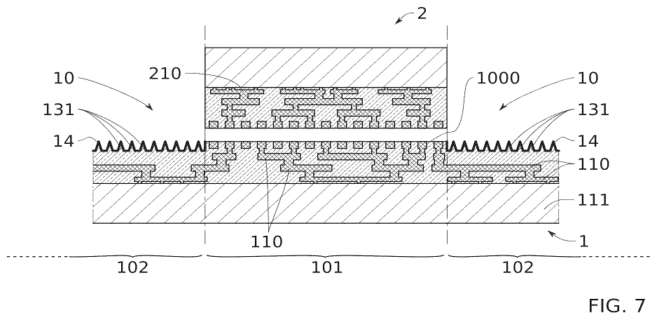

The first step of this method consists of providing a substrate 11 comprising a first level 111 with the basis of a semiconductor material and a second level 112 with the basis of a dielectric material, the second level 112 extending over the first level 111, so as to have an exposed surface 1121. In the illustrated example, the semiconductor material with the basis of which the first level 111 is constituted, is silicon and the dielectric material with the basis of which the second level 112 is constituted, is silicon oxide. However, the dielectric material with the basis of which the second level of the provided substrate is constituted, is not necessarily an oxide of the material with the basis of which the first level of the substrate is constituted. Moreover, semiconductor materials other than silicon are considered, for example, that they can be structured by photolithography and dry etching techniques, potentially involved in the implementation of the method according to the first aspect of the invention; this will be typically the case for germanium, sapphire, etc. In this case, it is noted that the second level 112 of the substrate 11 has a thickness e less than 10 μm; this thickness e will further be greater than the height of the terminals 131 with the basis of the dielectric material that the method makes it possible to manufacture on the substrate 11 surface; it will be even, if necessary, greater than the height of the terminals 131 and than the height of an electrical interconnection level 110 buried in the dielectric material of the second level 112 (see FIG. 7). The dielectric terminals 131 can indeed be intended to be formed in an upper layer of the second level 112 of the substrate 11, which has no electrical interconnection at all, such that their formation makes it possible to preserve the integrity of said electrical interconnections, when they exist.

In reference to FIG. 3B, the method according to the first aspect of the invention further comprises the formation, on the exposed surface 1121 of the second level 112 of the substrate 11, of a layer with the basis of a sacrificial material 12, below called “sacrificial layer 12”. The sacrificial material can be a resin, and more specifically, a photosensitive or thermosetting or electrosensitive resin (in the case of electronic photolithography). The sacrificial layer 12 is formed, so as to have a first zone 1201 over which a solid layer 121 with the basis of said sacrificial material extends, and a second zone 1202 over which a plurality of micrometric or nanometric 122 terminals with the basis of said sacrificial material extends, below called “sacrificial terminals 122”. In FIG. 3B, a second zone 1202 has been represented on either side of the first zone 1201, but FIG. 3B illustrates a cross-sectional view, and each first zone 1201 is indeed surrounded by a second zone 1202.

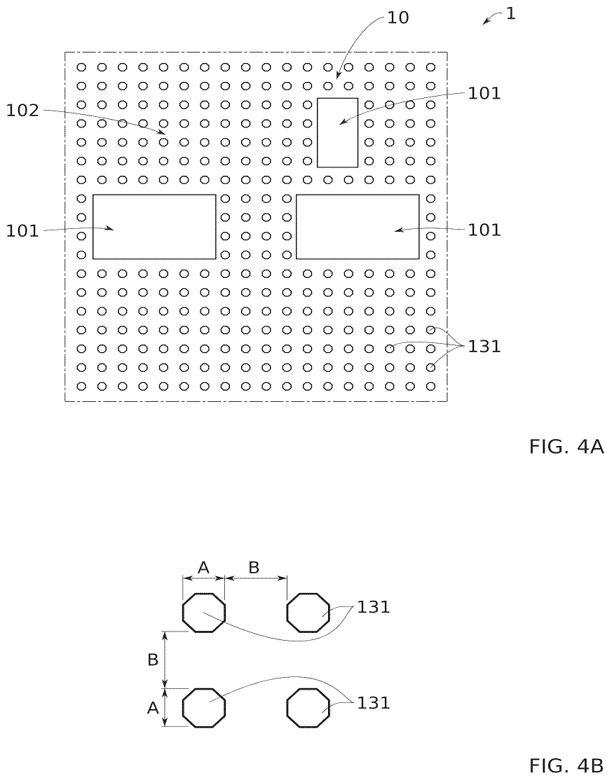

FIG. 4A offers a top view of an embodiment of a wafer 1 according to the second aspect of the invention, on which it appears that each solid zone 101 is actually surrounded by a structured zone 102, which assumes a corresponding distribution of each first zone 1201 and of the second zone 1202 which surrounds it. In this case, it is noted that FIG. 4A also makes it possible to illustrate that a receiving surface of a microelectronic component 2 is not necessarily circular or square, but can accommodation shape variations, being understood that it is likely that the greater the shape ratio of this receiving surface is, the greater the risk of obtaining an inaccurate alignment of the microelectronic component 2 on the receiving surface will be.

Furthermore, each first zone 1201 extends over a surface greater than a micrometric or nanometric surface, over which each sacrificial terminal 122 extends. Preferably, the surface of each first zone 1201 is greater than at least one order of magnitude on the surface over which each sacrificial terminal 122 extends. In this case, it is noted that, on the illustration that FIG. 3B offers, all the sacrificial terminals 122 have the same dimensions and are regularly spaced apart, any variation of this matrix arrangement can be considered, as long as it enables the manufacturing of a wafer 1 according to the second aspect of the invention. It can, in particular, be considered that the sacrificial layer 12 obeys a design making it possible to ultimately have density gradients of dielectric terminals 131 on the surface of a structured zone 102, which would make it possible to have wettability gradients between joint surfaces.

As will be seen below, the surface over which each first zone 1201 extends is intended to form a receiving surface of a microelectronic component 2; its dimensions are therefore mainly limited by the dimensions of said microelectronic component 2, or by those of a mesa formed on the surface of the microelectronic component 2 defining a transfer surface of said component on the wafer 1. In this sense, the sacrificial layer 12 can be formed, such that each solid zone 1201 has at least one transverse dimension of between 100 μm and 20000 μm, preferably between 500 μm and 5000 μm, and even more preferably, substantially equal to 2000 μm.

The dimensions of the sacrificial terminals 122 are themselves limited by the desired aim, reached in terms of wettability contrast between solid zone 101 and structured zone 102 of the main surface 10 of the wafer 1. The sacrificial terminals 122 indeed have dimensions which predetermine those of the terminals made of a dielectric material 131, below called “dielectric terminals 131”, that will be described below, and the dimensions of the spaces which separate these dielectric terminals 131 from one another; these dimensions, defining the drop angle β on the surface of the micro-structuration that the dielectric terminals 131 produce, therefore impact on the wettability contrast that the manufactured wafer 1 will have.

The dimensions of the dielectric terminals 131 and the spaces which separate these terminals from one another, are preferably such that:
a. each sacrificial terminal 122 has at least one transverse dimensions of between 100 nm and 2 μm, preferably between 200 nm and 1 μm, and even more preferably, substantially equal to 500 nm, and/or
b. two sacrificial terminals 122, adjacent to one another, of one same plurality are spaced apart from one another by a distance of between 100 nm and 1 μm, preferably between 200 nm and 800 nm, and even more preferably, substantially equal to 500 nm.

Furthermore, the sacrificial layer 12 is preferably formed, so as to have a substantially constant thickness of between 200 nm and 5 μm, preferably between 500 nm and 1.5 μm, and even more preferably, substantially equal to 800 nm. As will be seen below, the thickness of the sacrificial layer 12 determines, together with its nature and the etching method implemented, the height of the dielectric terminals 131, and therefore impacts on the wettability contrast which will be obtained.

If it is preferable that the sacrificial layer 12 has a substantially constant thickness between the different solid 101 or structured 102 zone(s), the manufacturing method according to the first aspect of the invention is however not limited to this. For example, the sacrificial layer 12 could be formed, such that the thickness of the sacrificial layer 12 on each solid zone 101 is greater than the height of the sacrificial terminals 122, for example, so as to be able to push the overetching described below farther, without consuming all of the present sacrificial material, before the overetching, on each solid zone 101.

According to a preferred embodiment of the manufacturing method according to the first aspect of the invention, the formation of the sacrificial layer 12 comprises a photolithography step, i.e. a standard microelectronic step, controlled and broadly modulable. All the same, it is specified that such a photolithography step can comprise the following substeps:
a. Depositing a solid layer with the basis of said sacrificial material on the exposed surface 1121 of the second level 112 of the provided substrate 11,
b. Exposing the layer with the basis of said sacrificial material to a light radiation through a photolithography mask, structured so as to define a negative or a positive of the desired micro-structuration of the layer with the basis of said sacrificial material, then.
c. Chemically etching the layer with the basis of said sacrificial material, so as to obtain the desired micro-structuration.

Alternatively, the formation of the layer with the basis of said sacrificial material comprises at least one screen-printing step.

In reference to FIG. 3C, the method according to the first aspect of the invention further comprises the etching of a part of the previously formed sacrificial layer 12, and a part of the second level 112 of the substrate 11. The etching is more specifically such that a solid zone 100 at each first zone 1201 and a structured zone 102 at each second zone 1202 are formed, in the second level 112 of the substrate 12, each structured zone 102 having a plurality of dielectric terminals 131 which corresponds, as announced above, to the plurality of sacrificial terminals 122, and each dielectric terminal 131 having a cross-section, the dimensions and the shape of which correspond to those of the sacrificial terminal 122. For example, in reference to FIGS. 4A and 4B, if the sacrificial terminals 122 have an octagonal cross-section of characteristic size A equal to 500 nm between two opposite edges and are spaced apart by a minimum distance B of between 300 nm and 1 μm, the corresponding dielectric terminals 131 will have the same octagonal cross-section, and will be spaced apart by one same minimum distance. Other shapes are naturally possible (round, square, etc.).

The plurality of dielectric terminals 131 extending from each structured zone 102 gives the exposed surface of the structured zone 102 its superhydrophobic character, by creating the observation conditions of a lotus effect. However, the superhydrophobic character that the plurality of dielectric terminals gives the exposed surface of each structured zone 102 will be more or less pronounced according to the way in which the etching is performed.

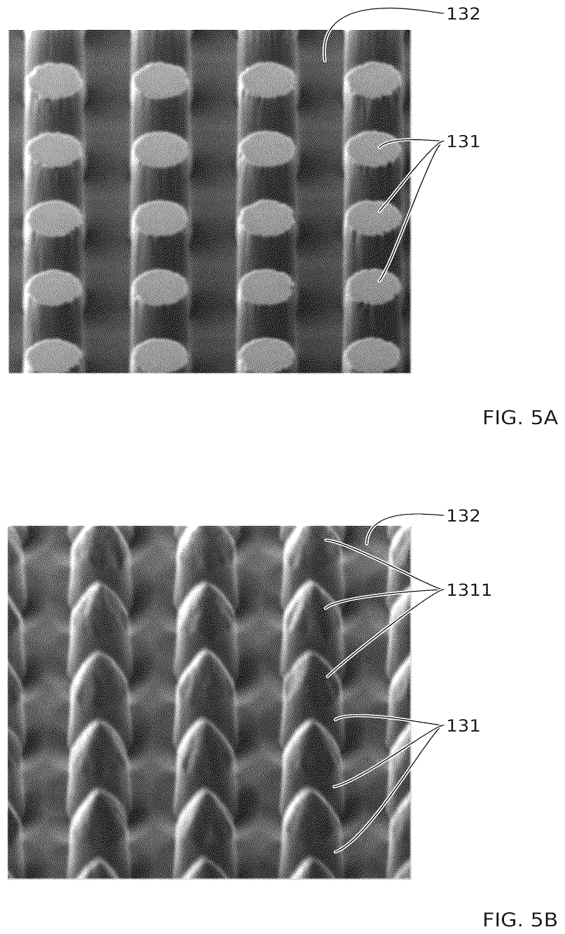

In the field of microelectronics, the standard implementation of such an etching, that it is linked to an exposure to an etching plasma or to an ion etching, would aim for the formation of pillars such as illustrated in FIG. 5A. These pillars, which each have a substantially constant cross-section from their base up to their vertex, can be identified at the dielectric terminals 131. However, it is preferable, in order to increase the wettability contrast between a solid zone 101 and the structured zone 102 which surrounds it, that the dielectric terminals 131 have a developing cross-section, by decreasing from its base or from a non-zero distance to its base, and up to its vertex. For example, it is preferable that each dielectric terminal 131 has an ogive-shaped or pinhead-shaped end, as illustrated in FIG. 5B. To obtain this advantageous shape of the dielectric terminals 131, the etching can simply be continued, beyond what is done in a standard manner, up to obtaining a lift-off of the sacrificial terminals 122; overetching can thus be referred to, as already mentioned above. Thus, an etching step pushed sufficiently far, and more specifically, pushed beyond the standard (which only provides a partial consumption of the sacrificial material), such that the sacrificial material constituting the sacrificial terminals 122 are completely consumed by the only etching, makes it possible to obtain dielectric terminals 131 with a sharp head, such as illustrated in FIG. 5B, giving a superhydrophobic character to the structured zone 102, with a drop angle substantially equal to 160°, advantageously increased relative to that which would give flat-head dielectric terminals to the structured zone 102, such as illustrated in FIG. 5A.

The difference, of at least one order of magnitude, between the transverse dimensions of the solid layer 121 and those of each sacrificial terminal 122 makes it possible to result in this. Indeed, it is observed that, thus the sacrificial material is more rapidly consumed, during etching, on the narrow patterns that the sacrificial terminals 122 constitute, that the sacrificial material is not the largest pattern that the solid layer 121 constitutes. Thus, from the overetching, a solid layer 121′ of thickness less than the solid layer 121 to the right of the solid zone 101 remains, such as illustrated in FIG. 3C. This observation can be explained as being due to a faceting phenomenon. This phenomenon conveys the fact that, during etching, a lateral consumption of these materials is added to the consumption from above of the sacrificial material and of the dielectric material with the basis of which the second level 112 of the substrate 11 is constituted; yet, the lateral consumption is increased on small patterns relative to larger patterns, when one same etching is applied to them. It is noted, that in FIG. 3C, the consequences of the faceting phenomenon on the shape of the formed dielectric terminals 131 are roughly schematised by illustrating each terminal in the form of a cone cross-section.

However, the extension of the etching, beyond the standard, is preferably exceptionally limited, and this, at least for the two reasons given below.

The first of these two reasons is that it is indeed advantageous that the etching is stopped before obtaining a lift-off of the sacrificial material to the right of each first zone 1201. In this way, at the end of etching, and more specifically, at the end of overetching, a thickness of the sacrificial material remains to the right of each first zone 1201, this thickness preferably being between 100 nm and 5 μm.

The second of the two reasons to not extend the etching, beyond the obtaining of a lift-off of the sacrificial material 12 to the right of each second zone 1202, is that the dielectric terminals 131 are reduced in dimensions and, in particular, in height; yet, it is preferable that the etching is configured, such that each dielectric terminal 131 has a height of between 100 nm and 5 μm, preferably between 400 nm and 2.5 μm, and even more preferably, substantially equal to 1 μm.

In reference to FIG. 3D, the method according to the first aspect of the invention can further comprise, following the etching, the deposition of a layer, preferably conform, with the basis of a hydrophobic material 14, below called “hydrophobic layer 14”. For example, the hydrophobic material, with the basis of which the hydrophobic layer 14 is constituted, is preferably with the basis of at least one polymer. It comprises, for example, a 0.1% by mass fluorosilane polymer in a hydrofluoroether carrier solvent. For example, this can be a coating known under the commercial name: 3M™ Novec™ 1720 Electronic Grade Ultra Fine. Any material known for its hydrophobic properties in the context of the present invention can be considered, and the examples given above are not limiting of the invention. For example, the deposition of the hydrophobic layer comprises a spin coating step or a plasma deposition step. Naturally, the hydrophobic layer 14 advantageously makes it possible to contribute to increasing the wettability contrast between solid zone 101 and structured zone 102.

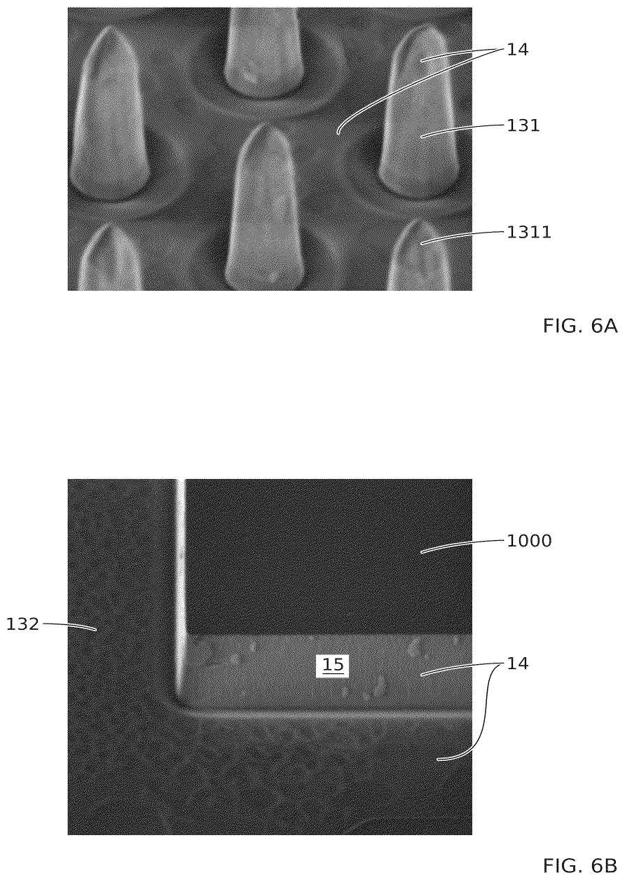

Preferably, and as illustrated in FIGS. 6A and 6B, the deposition of the hydrophobic layer 14 is configured, such that the hydrophobic layer 14 covers each dielectric terminal 131 and each space 132 between the dielectric terminals 131 or between the dielectric terminals and the mesa 15 that the solid zone constitutes, even if necessary, the side edges 1011 of said mesa 15. It is noted that it appears, in this case, that if it is interesting to push the etching up to consuming all the sacrificial material to the right of the second zones 1202 to obtain the faceted dielectric terminals 131, such an overetching is also interesting, in that it enables the deposition of the hydrophobic layer 14 on and between the dielectric terminals 131, without requiring a step of removing the sacrificial material, that it would otherwise remain to the right of the second zones 1202. Moreover, being preferred that the etching does not relate to all the sacrificial material formed to the right of the first zone 1201, the deposition of the hydrophobic layer 14 also results in, in this case, the covering of the sacrificial material remaining to the right of the first zone 1201, at least on its upper face, and potentially, on its flanks; this situation is that illustrated in FIG. 3D.

In reference to FIG. 3E, the method according to the first aspect of the invention can further comprise, preferably following the deposition of the hydrophobic layer 14, a removal step from what possibly remains of the sacrificial layer 12, and more specifically, of the part of the sacrificial layer 12 which has been preserved to the right of the first zone 1201 following the etching. This removal makes it possible to expose a surface 1000 of the second level 112 of the substrate 11 which is located to the right of each first zone 1201. In this case, it is noted that this surface 1000 is also illustrated in FIGS. 2 and 7. It is therefore understood, in view of FIGS. 3D and 3E, that proceeding with the deposition of the hydrophobic layer 14 before the removal of what remains of the sacrificial layer 12 following the etching enables, at the same time, the removal of the hydrophobic layer 14 which covers what remains of the sacrificial layer 12, in particular, at the solid zone 101, following the etching. Subsequently, as long as the material with the basis of which the second level 112 of the substrate 11 is constituted is hydrophilic, which is, in particular, the case of silicon oxide, the wettability contrast between the solid zone 101 and the structured zone 102 is advantageously significantly increased. It is noted that the drop angle a of water on such a silicon oxide-based hydrophilic surface, is typically less than 10°.

It will be noted that the wafer such as illustrated in FIG. 3E corresponds to the wafer such as illustrated in FIG. 2. In other words, from the step of the method represented in FIG. 3E, a wafer 1 has been manufactured, which is suitable for the self-assembly of microelectronic components 2 on the wafer 1 by die-to-wafer-type hybrid bonding.

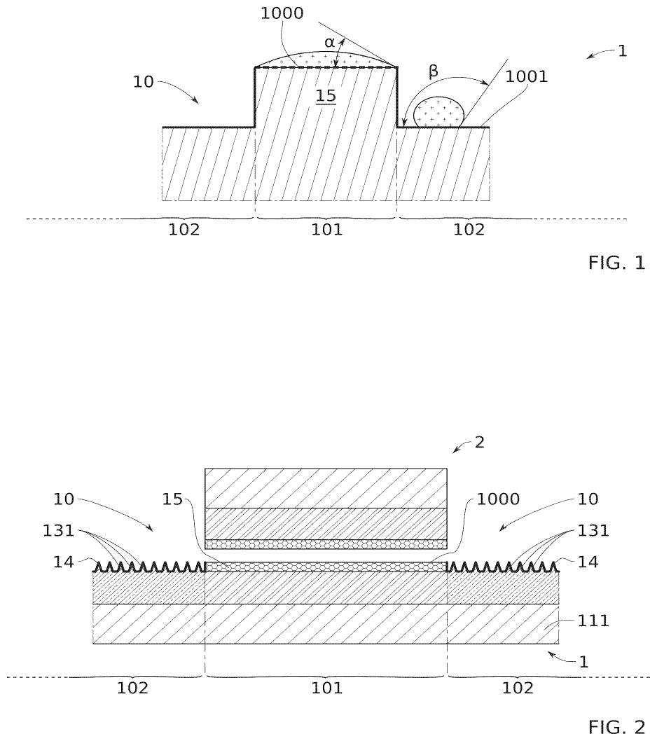

FIG. 7 makes it possible to illustrate a more specific case, and not excluded from the considerations above, in which the second level 112 of the substrate 11 comprises at least one electrical interconnection level 110 extending from a solid zone 101 to a structured zone 102. More specifically, the electrical interconnections are buried, or equivalently encapsulated, in the dielectric material with the basis of which the second level 112 of the substrate 11 is constituted. The electrical interconnections are flush with the second level 112 of the substrate 11 from the exposed surface 1000 of each solid zone 101, to enable an electrical reconnection with a microelectronic component 2 intended to be removed on the solid zone 101. On the contrary, the electrical interconnections are buried, or equivalently encapsulated, in the dielectric material with the basis of which the second level 112 of the substrate 11 is constituted, at each structured zone 102. The depth at which these interconnections are buried determines the thickness of the second level 112 of the substrate 11 which can be dedicated to the formation of the dielectric terminals 131, if it is sought that the etching does not alter the integrity of the buried interconnections. It is thus shown that the manufacturing method according to the first aspect of the invention is compatible with a self-assembly method, resulting in the transfer of microelectronic components electrically operationally connected to one another via the receiving wafer 1, the electrical interconnection level extending from a solid zone 101 to an adjacent structured zone 102, even beyond. The preservation of the integrity of electrical interconnections indeed assumes that the etching is stopped before the electrical interconnections are reached by it. It is therefore possible, to provide, during the manufacture of the substrate 11 such as provided, that the electrical interconnection level at the level of which is intended to form a structured zone 102 is covered by a sufficiently thick layer of dielectric material, such that the dielectric terminals 131 of the desired geometry can be etched in this layer, and does not require to etch the electrical interconnections. Moreover, it will be noted that the height of the dielectric terminals 131 obtained by implementation of the method according to the first aspect of the invention is substantially equal to the height of the mesa 15 obtained by this same implementation. Relative to the receiving wafers known from the prior art, and for example, relative to a wafer according to the example given in FIG. 1, the mesa 15 obtained by implementation of the method according to the first aspect of the invention is advantageously reduced, and if this reduction does not increase the wettability contrast between the solid zone 100 and the structured zone 102 which surrounds it:
a. it facilitates the industrial integration of the method according to the first aspect of the invention, and
b. the microroughness that the micro-structuration obtained by implementation of the method according to the first aspect of the invention gives to the structured zone 102, makes it possible to broadly compensate for the possible decrease of performance in terms of self-alignment which would result from this.

The manufacturing method according to the first aspect of the invention therefore enables the manufacture of a wafer 1 according to the second aspect of the invention, and more specifically, a receiving wafer 1 intended for the transfer of microelectronic components 2 by hybrid bonding, each solid zone 101 being intended to receive a microelectronic component 2 and each structured zone 102 being intended to constitute at least one part of a zone between microelectronic component 2.

More specifically, such a wafer 1 mainly comprises a main surface 10 having at least one solid zone 101 and one structured zone 102 having, between them, a wettability contrast greater than 90°, and preferably greater than 120°, each micro- or nano-structured zone 102 extending around a solid zone 101, the wafer comprising a substrate 11 which comprises a first level 111 with the basis of a semiconductor material and a second level 112 with the basis of a dielectric material, the second level 112 extending over the first level 111, said at least one solid zone 101 and each structured zone 102 being formed in the second level 112 of the substrate 11 and each micro- or nano-structured zone 102 having a plurality of terminals with the basis of said dielectric material 131.

And, when the etching is an overetching consuming all the sacrificial material formed to the right of each second zone 1202, the dielectric terminals 131 of the wafer 1 have faceted ends 1311, for example, such as illustrated in FIG. 5B, so as to obtain a further increased wettability contrast, and easily brought to a value greater than 120°, even greater than 140°.

More specifically, the wafer 1 according to the second aspect of the invention can be such that:
a. each dielectric terminal 131 has a height of between 100 nm and 5 μm, preferably between 400 nm and 2.5 μm, and even more preferably, substantially equal to 1 μm, and/or
b. each dielectric terminal 131 has at least one transverse dimension between 100 nm and 2 μm, preferably between 200 nm and 1 μm, and even more preferably, substantially equal to 500 nm, and/or
c. two dielectric terminals 131 adjacent to one another of one same plurality, as spaced apart by a distance of between 100 nm and 1 μm, preferably between 200 nm and 800 nm, and even more preferably, substantially equal to 500 nm, so as to give the surface of the structured zone 102, a superhydrophobic character, that the dielectric terminals 131, even the space 132 between these terminals, are covered or not by a hydrophobic coating 14.

The invention also relates, according to a third aspect, to the self-assembly method implementing the receiving wafer 1 according to the second aspect of the invention, and the assembly 0 obtained by implementation of the self-assembly method according to the third aspect of the invention.

It will be appreciated that, thanks to the present invention:
a. it can be sufficient to add one single photolithography level applied to the substrate 11 such as provided to make it best suitable for self-assembly; and/or
b. the etching step making it possible to generate a microroughness is a standard and fully controlled microelectronic step, which does not generate defects nor particles. It is very easy to integrate, in a method for producing dies and uses the same types of equipment as the preceding steps of said production method; and/or
c. the shape, the size and the density of the generated dielectric terminals 131 are fully controllable, since they correspond to patterns drawn on the added photolithography level. In the same way, the distance between the receiving zone of the die 2 (hydrophilic zone) and of the inter-die zone (superhydrophobic zone) is modulable, also since it is defined by the design of the sacrificial layer 12, which is not the case for black silicon that the scientific article mentioned in the introduction makes it possible to obtain; and/or
d. it is not necessary to remove all the insulating and metal materials, constituting the electrical interconnections 110, which can be very numerous in the inter-die zones, and difficult to remove by etching, given their variety; and/or
e. it is avoided to generate a very large mesa 15 on the surface of the dies and of the receiving wafer 1, this mesa, all the same, being obtained so as to contribute to reaching a high wettability contrast between the solid zone 101 and the structured zone 102.

The invention is not limited to the embodiments described above and extends to all the embodiments covered by the claims.

1. A method for manufacturing a wafer comprising a main surface having at least one solid zone and one micro- or nano-structured zone having, between the two zones, a wettability contrast greater than 90°, each micro- or nano-structured zone extending around a solid zone the method comprising:
providing a substrate comprising a first level with the basis of a semiconductor material and a second level with the basis of a dielectric material, the second level extending over the first level,
forming, on an exposed surface of the second level of the provided substrate, a layer with the basis of a sacrificial material, having at least one first zone over which a solid layer with the basis of said sacrificial material extends, and a second zone over which a plurality of micrometric or nanometric terminals with the basis of said sacrificial material extends, each first zone being surrounded by a second zone and each first zone extending over a surface, of at least one order of magnitude, greater than a micrometric or nanometric surface, over which each terminal with the basis of said sacrificial material extends, and
etching a part of the layer with the basis of said previously formed sacrificial material and a part of the second level of the substrate, so as to form, in the second level of the substrate, said at least one solid zone at each first zone and each micro- or nano-structured zone at each second zone, each micro- or nano-structured zone having a plurality of terminals with the basis of said dielectric material which corresponds to the plurality of terminals with the basis of said sacrificial material.

2. The method according to claim 1, wherein the etching comprises an overetching of the terminals resulting in a lift-off of the terminals with the basis of said sacrificial material.

3. The method according to claim 1, wherein the formation of the layer with the basis of said sacrificial material comprises a photolithography step.

4. The method according to claim 1, wherein the etching is stopped before obtaining a lift-off of the layer with the basis of said sacrificial material to the right of each first zone, the layer with the basis of said sacrificial material remaining to the right of each first zone preferably having a thickness of between 100 nm and 5 μm.

5. The method according to claim 1, further comprising, following the etching, the deposition of a layer with the basis of a hydrophobic material.

6. The method according to claim 5, wherein the deposition of the hydrophobic layer is configured, such that the hydrophobic layer covers each terminal with the basis of said dielectric material and each space between the terminals with the basis of said dielectric material of one same plurality, even if necessary, the side edges of each solid zone.

7. The method according to claim 6, further comprising removing a part of the layer with the basis of said sacrificial material, which remains to the right of the first zone after the etching, so as to expose a surface of the second level of the substrate, which is located to the right of each first zone.

8. The method according to claim 7, wherein the deposition of the hydrophobic layer is implemented before the lift-off of the part of the layer with the basis of said sacrificial material which remains to the right of the first zone after the etching.

9. The method according to claim 1, wherein the wafer constitutes a receiving wafer, for the transfer of microelectronic components by hybrid bonding, each solid zone to receive a microelectronic component and each micro- or nano-structured zone to constitute at least one part of a zone between microelectronic components.

10. The method according to claim 1, wherein the layer with the basis of said sacrificial material is formed, such that the terminal has at least one transverse dimension of between 100 nm and 2 μm.

11. The method according to claim 1, wherein the layer with the basis of said sacrificial material is formed, such that two terminals adjacent to one another of one same plurality are spaced apart from one another by a distance of between 100 nm and 1 μm.

12. The method according to claim 1, wherein the etching is configured, such that each terminal with the basis of said dielectric material has a height of between 100 nm and 5 μm.

13. A wafer comprising a main surface having at least one solid zone and one micro- or nano-structured zone having, between the two zones, a wettability contrast greater than 90°, each micro- or nano-structured zone extending around a solid zone, the wafer comprising a substrate which comprises a first level with the basis of a semiconductor material and a second level with the basis of a dielectric material, the second level extending over the first level, said at least one solid zone and each micro- or nano-structured zone being formed in the second level of the substrate and each micro- or nano-structured zone having a plurality of terminals with the basis of said dielectric material, wherein the wafer the terminals with the basis of said dielectric material have faceted ends.

14. The wafer according to claim 13, further comprising a hydrophobic layer covering each terminal with the basis of said dielectric material and each space between the terminals with the basis of said dielectric material of one same plurality, even if necessary, side edges of each solid zone, and not covering said at least one solid zone.

15. The wafer according to claim 13, wherein:
each terminal with the basis of said dielectric material has a height of between 100 nm and 5 μm, and/or
each terminal with the basis of said dielectric material has at least one transverse dimension of between 100 nm and 2 μm, and/or
two terminals with the basis of said dielectric material adjacent to one another of one same plurality are spaced apart from one another by a distance of between 100 nm and 1 μm.

16. The wafer according to claim 13, further comprising a receiving wafer for the transfer of microelectronic components, such as microelectronic dies, by hybrid bonding, each solid zone to receive a microelectronic component, and each micro- or nano-structured zone to constitute at least one part of a zone between microelectronic components.

17. The wafer according to claim 16, wherein the second level of the substrate comprises at least one electrical interconnection level extending at least to the right of each solid zone and extending, if necessary, from a solid zone to an adjacent micro- or nano-structured zone, the electrical interconnections being flush with the second level of the substrate from an exposed surface of each solid zone and extending from each solid zone at least up to the adjacent micro- or nano-structured zone, and extending, more specifically, below the plurality of terminals with the basis of said dielectric material of said adjacent micro- or nano-structured zone, by being encapsulated in the dielectric material with the basis of which the second level of the substrate is constituted.

18. A method for self-assembling microelectronic components implementing the wafer according to claim 13.

19. The self-assembly method according to claim 18, wherein a plurality of microelectronic components are self-assembled on the wafer by die-to-wafer-type hybrid bonding.

20. An assembly; comprising:
the wafer according to claim 13; and
a plurality of microelectronic components assembled on the wafer by hybrid bonding.
